(19) United States
(12) Patent Application Publication
(10) Pub. No.: US 2006/0108508 A1
(43) Pub. Date: May 25, 2006

(54) Method and apparatus for high speed imaging

(76) Inventor: Najeeb Khalid, Westmount (CA)

Correspondence Address: OGILVY RENAULT LLP, 1981 MCGILL COLLEGE AVENUE, SUITE 1600, MONTREAL, QC, H3A2Y3, CA

(21) Appl. No.: 11/222,863

(22) Filed: Sep. 12, 2005

(30) Foreign Application Priority Data
Mar. 12, 2004 (CA) CA2004/000364

(51) Int. Cl. H01L 27/00

(52) U.S. Cl. 250/208.1

(57) ABSTRACT

A novel method and apparatus is described for imaging at high speed from digital data. This method is an improvement on the present art in two significant manners. The means for generating the light and the use of large number of independent light sources in an internal drum imaging geometry, when combined together provide a very cost effective solution to improve imaging times by a factor of ten or more.

### CROSS REFERENCED TO RELATED APPLICATIONS

This application claims priority of U.S. provisional patent application Ser. No. 60/453,832 filed Mar. 12, 2003, and is a continuation application of PCT serial number CA2004/000364 filed Mar. 12, 2004, both of which are hereby incorporated by reference.

### FIELD OF THE INVENTION

The present invention relates to imaging, and more specifically the present invention relates to high speed imaging as applied to photosensitive materials such as film, printed circuit laminates and printing plates, both for creating images and for reading images.

### BACKGROUND OF THE INVENTION

Imaging is a marriage of the laser source with the plate. Printing Plates and other photosensitive materials are sensitive to certain wavelengths and require a specific amount of energy per cm square, i.e. the energy density. The energy density is measured in joules/cm/cm.

Typical values for different plates are:

| | | |
|---|---|---|
| Conventional analog plates | 400 | mJ/cm/cm |
| Thermal plates | 250 | mJ/cm/cm |
| Citiplate ™ | 5 | mJ/cm/cm |
| Photopolymer violet plates | 50 | μJ/cm/cm |
| Silver violet plates | 5 | μJ/cm/cm |

Energy is the product of power (P) and time (t). Energy (E) is measured in J/cm/cm, power in watts/cm/cm, and time in seconds. Therefore to expose a plate in an imaging system the dot time and the power density are inversely related, and as the object is to get the smallest imaging time for the complete plate, the power has to be the highest. This puts pressure on the design of the laser source and the laser control.

Thus, power is reciprocal to time. Increase power and you have to decrease time to get the same energy, or decrease power and increase time for the same effect. This relationship allows us to choose the correct mix of time and power for a given application and result.

### EXAMPLE

To image on a photopolymer violet plate requiring 50 μcm/cm, and the rotating mirror rotating at 24,000 rpm (10 nanosecond), the laser power required will be:
50*10⁻⁶=P*10⁻⁸
or P=50*10⁻⁶/10⁻⁸
or P=5000 W/cm/cm
area of the dot is approx 80 square microns for 2540 dpi
therefore the power of the laser beam should be 4 mW

The art of imaging at high resolution from digital data has produced numerous designs relying on raster scan or projection imaging. All these designs have reached a level of performance that cannot be improved without complexity and cost penalties. Increasing the speed of imaging encounters numerous challenges that yet have to be overcome.

Imaging requires a specific amount of energy be incident on the surface, measured as joules per square centimeter. As E=P*t, power and time being reciprocal, the designer has a choice in finding the appropriate mix of the two variables. There is limit imposed by breakdown of reciprocity, thus P and t cannot be infinitely small or large.

Therefore, in order to decrease the time required to image, t being very small, P, i.e. power then becomes very large. The constraint on power is the availability of a light source with a wavelength similar to the wavelength the material is sensitive to. The light sources are limited in choice.

Therefore the only method to obtain high imaging speed is to increase the number of beams. This increases costs, as laser light sources used in this art are expensive. As discussed in the present art below, all known methods of imaging have limitations in speed.

Known methods for imaging on plates will be described herein below followed by a brief introduction to the physics of imaging.

Imaging on plates can be accomplished through three different strategies: external drum, internal drum, flat bed. Every so often, non-traditional methods have been tried but none have succeeded commercially. The only nominal success may be granted to Baysys Print, although the imaging time is 30 minutes and the quality is not good enough for commercial printing.

External Drum

In this classical design, the plate is wrapped around a metal cylinder and rotated about the axis of the cylinder. A laser beam, or a number of laser beams are focused on the rotating cylinder in an orthogonal manner such that as the laser beams, mounted on a carriage, moves parallel to the axis of the cylinder, they trace a set of helical lines. Thus a complete x-y scan of the plate is possible.

The disadvantages of this system, compared to others, are that the speed of the cylinder is limited due to its mass. Therefore, in order to increase imaging throughput, the number of laser beams has to be increased. As the energy required by the plate increases, the lasers become expensive. Due to the precision required and the need to accommodate various plate sizes and weights, the loading and holding mechanism become complicated and therefore expensive.

The only advantage is that this is the only manner, to date, in which high-energy plates (thermal) can be imaged.
imaging time=length of plate the laser moves across*dpi/(RPS of cylinder*number of beams)
Example: a CREO Trendsetter™
plate length=40 inches
RPS of cylinder=RPM/60=500/60=8.33
number of beams=64
dpi=2400
imaging time=40*2400/8.33*64=96000/533.33=187.5 seconds=3.1 minutes
   Internal Drum

In this design, first implemented by Escher-Grad in the graphic arts market, the internal surface of a cylinder is used to position the plate; there is no motion. The XY scan is accomplished by the use of a rotating mirror traveling along the axis of the cylinder with a laser beam focused on the mirror. The mirror being a truncated cylinder, the focus point of the laser beam is rotated through 360 degrees with every rotation of the mirror.

This system does not require complex plate holding mechanisms and the moving parts are limited to two simple components. This lowers the cost dramatically, resulting in very cost effective designs that are equal or better than the quality produced by external drum designs. Throughput is equal or better due to a small rotating mass of the mirror.

The disadvantage is that high-energy plates cannot be exposed easily in this design.
imaging time=length of plate mirror moves over*dpi/RPS of rotating mirror
   Example: Escher Grad Cobalt 8™
plate length=30 inches
RPS=400 revolutions per second (24,000 RPM)
Dpi=2400
imaging time=30*2400/400=180 seconds=3 minutes
   Flat Bed

Again this is a classical design, and is in use in numerous applications from laser printers to direct wafer imaging. This design uses a multiple facet rotating mirror, reflecting a number of focused laser beams the focal points of which describe a complex surface. The complex surface is a concavely curved surface that is part of the surface of a cylinder. A flat field lens is used convert this complex surface to a flat surface with some remaining artifacts. The plate is placed on a flat bed and moved orthogonal to the rotating beams.

This design has the advantage of being able to provide very high throughput of imaging due to multiple facets and multiple beams. The disadvantage is the flat field lens is difficult to fabricate for large scan width and high quality imaging, thus increasing the cost.
imaging time=length of plate moved across the scan over*dpi/RPS of rotating mirror*facets*number of beams
   Example for the flat bed system:
plate length=40 inches
RPS=100 revolutions per second (6,000 RPM)
number of facets=8
number of laser beams=8
dpi=2400
imaging time=40*2400/(100*8*8)=96000/6400=15 seconds=0.25 minutes

In external drums design the dot time is large as the rotation speed is slow, the solution is to increase the number of beams, increasing costs. Further increase in number of beams from where they are today requires higher selling prices. In internal drum designs, the dot time is very low but it is not practical to increase the number of beams. The laser power is limited by what is available. In flat bed design the problem is the flat field lens. No present method exists to increase the imaging throughput significantly without substantial increase in costs.

U.S. Pat. No. 4,814,606 describes a scanner in which an X-ray or radiograph is placed in a circular cross-section support and scanned using a scan beam directed via a rotating multifaceted mirror. The light transmitted through the radiograph is detected by a curved detector arranged on an opposite side of the support. The optical arrangement ensures that the beam shape impinging on the radiograph is not distorted. It is disclosed in the reference that the laser scanning apparatus provides constant pathlength to the radiograph, constant velocity of the spot of interrogating radiation across the radiograph, constant incidence angle of the beam onto the radiograph and, as a consequence of the latter, constant pathlength through the radiograph. It is also stated therein that the combination of the rotating mirror, along with the short response time of the photodetector, provides a scanning apparatus with increased scanning speed. However, in a scanned image, a small variation in scan speed of, for example, a radiograph will result in a small variation in the acquired image in a predictable manner. While the reference teaches providing the mentioned properties, the object is to reduce artefacts due to the combination of all of the mentioned properties. A circular cross-section in combination with a flat multifaceted mirror does not provide a constant velocity of the scanning spot. The artefact resulting from this imprecision alone may not be important in the case of scanning an X-ray image, or can still be corrected in the scanned image. However, in the case of a scanning apparatus for writing or recording, no such correction is possible, and, as mentioned above, it is essential to ensure a constant power delivery to the recording surface.

### SUMMARY OF THE INVENTION

The proposed method and apparatus eliminates the obstacles to high speed imaging by combining a number of known technologies with a novel light source.

The novel approach described below rests on two fundamental advances, one through advances in light sources and the other in the use of a multiple facet mirror using a complex surface to eliminate the need for a flat field lens. The means for generating the light are improved, and the use of large number of independent light sources in an internal drum imaging geometry, when combined together provide a very cost effective solution to improve imaging times by a factor of ten or more.

The first advance is to replace the violet laser by LEDs of the same wavelength. Advances in LED technology have made it possible to obtain high power and high coupling efficiency from blue LEDs. The disadvantage remains that the switching time is not fast enough to replace laser diodes. In this novel approach the switching time is not a problem.

By arranging the LEDs in a matrix or an array such that n LEDs are placed with an accurate pitch of xₚ, the resulting light is composed of n light beams increasing uniformly in diameter. An optical system placed at a distance f₁ from the light source will then focus these beams at a focal length of F forming a matrix or line of spots of diameter dₒ at a pitch xᵢ. The array of LEDs is controlled by switched current sources connected to the output of a computing device such that any of the n LEDs forming the n beams can be switched in or off as a function of the digital data available to the computer. The electronics and software will then take care of the relative positing of the dots from each so as to form an integrated image.

The power of each such beam must meet the requirements of the material to be imaged. The power is reciprocal to the time. If time is large, power required is low. The number n, the number of beams, can be increased to overcome the increase in imaging time due to slower t.

A motor with a polygon prism is mounted on a rotor of the motor. The faces of the polygon are polished to form a flat mirror and the faces of the polygon are parallel to the axis of the motor.

The n light beams focused at distance F are made to be incident on one of the facets of the polygon mirror, the n beams are now reflected and focused at distance F, being the sum of F1, the distance from the lens of the light source to the facet of the polygon mirror, and F2, the distance from the facet of the polygon mirror to the focal point. As the rotor of the motor rotates, this focal point traverses a complex path.

As the facet on which the beams are reflecting off, rotates past the beams, the next facet starts to reflect the same beams. The reflected beams then return to an initial point and retrace the complex path described by the equation above again, this is repeated for each of the m facets. Thus each rotation of the motor causes m scans of the surface by n beams.

The total number of scans per second is then described by the equation:
n*m*s,
where s is the speed of the motor expressed as revolutions per second.

For example, a motor rotating at 10 RPS (s) with a polygon mirror of 8 facets (m) and number of beams being 32 (n), the number of can lines being beams 32*8*10=2560 scan lines per second.

The above assembly is then mounted on a linear motion system such that as the assembly moves the scan lines are orthogonal to the travel of the linear motion system. Thus as the motor rotates, the travel is equal to dᵢ*n*m per rotation of the polygon mirror motor.

If a surface can be formed where the surface profile is described by the equation above and is placed at a distance F2+D from the center of the rotating mirror, where D is the diameter of the mirror as measured from the facet to the center of rotation, any material placed on this surface will then be exposed to the energy of the n beams, m times per revolution.

By adding necessary subsystems such as vacuum systems for holding the material, the sensors and feedback control systems to control the speed of the motor, and the linear motion systems and the co-ordination of these subassemblies, all known arts, a complete imaging system can be formed.

According to one broad aspect of the invention, there is provided an apparatus for high speed scanning of a printing plate for image capture or creation. The apparatus comprises a printing plate support having a lengthwise axis and adapted to support a printing plate, at least one optoelectronic device for providing one of an image recording light source and an image light detector, a light beam optical relay system optically coupling the at least one optoelectronic device with a scanning imaging point on the printing plate. The relay system includes a rotating mirror for reflecting a beam of light to scan across the printing plate in a transverse direction, and a gantry for moving the beam in the lengthwise direction across the printing plate. At least one of the printing plate support and the rotating mirror is adapted to provide a substantially linear transverse direction scan speed on the printing plate as the mirror rotates substantially at a constant rotational speed, the relay system comprising

essentially reflective optics between the gantry and the printing plate. In this way, the apparatus operates without the use of a flat field or f-θ lens.

Preferably, the rotating mirror is flat, and the printing plate support is a cylinder including a concavely curved surface. Alternatively, the printing plate support may be flat, and the mirror may have a complex surface. Of course, it will be appreciated that a combination of complex surfaces may be used, although it is preferred for simplicity to maintain either the mirror surface or the plate support surface flat

Preferably, the rotating mirror is multi-faceted, and the scanning imaging point performs a helical scan.

### BRIEF DESCRIPTION OF THE DRAWING

The invention will be better understood by way of the following detailed description of a preferred embodiment with reference to the appended drawings in which:

FIG. 1 is an optical diagram of the scanning system of the preferred embodiment;

FIG. 2 is a detailed illustration of a support having a complex surface according to the preferred embodiment; and

FIG. 3 is a construction diagram illustrating the formula describing the complex shape of the support in the case of a flat polygonal rotating mirror according to the preferred embodiment.

### PREFERRED EMBODIMENT

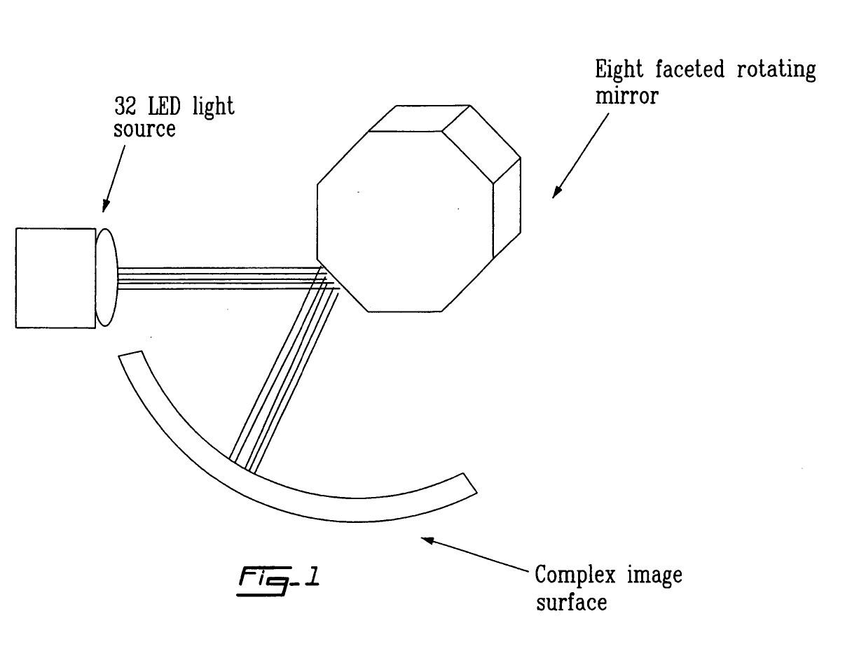

As shown in FIG. 1, an array of LEDs is formed on a ceramic substrate bonded with the 32 drivers and a connector to receive the digital signal to control the 32 LEDs is the light source. A lens that focuses the light beams at a distance of 350 mm forms the optics. The scanner is an eight faceted polygon mirror mounted on a static air bearing spindle with an encoder. The light source and the scanner are mounted in one assembly and aligned prior to mounting in the imaging engine.

The imaging engine comprises of a complex surface of length 1000 mm is formed by pouring a slurry composed of granite and quartz mixed with resins such that when poured over a form, will acquire the shape of the form to within the tolerances of the imaging system design. The width of this surface is 800 mm. The surface is computed for F to be 350 mm and D to be 150 mm. A linear motion system is mounted over this surface such that the travel is parallel to the surface and orthogonal to the complex form. The surface can hold material to be imaged on of a size 1000×800 mm. Thus the scan length will be 1000 mm and the linear motion will travel 800 mm.

When the light source and the scanner is mounted on this linear motion system and the motor is rotated, the 32 beams are reflected of each surface and can the complex surface 8 times per revolution. This arrangement results in 2560 scans per second for the motor rotation speed of 10 m RPS. An image at 1200 dpi and 1000×800 mm in size can be formed in =2560*30/2560=14 seconds, an improvement of over 20 times over the present art.

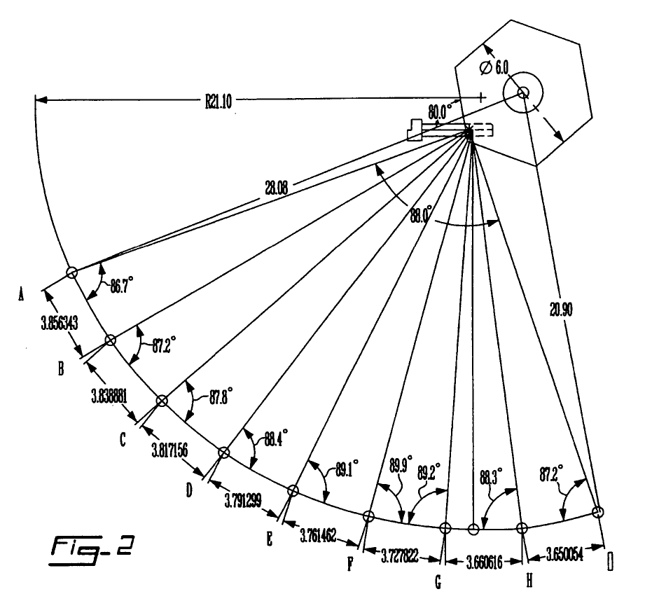

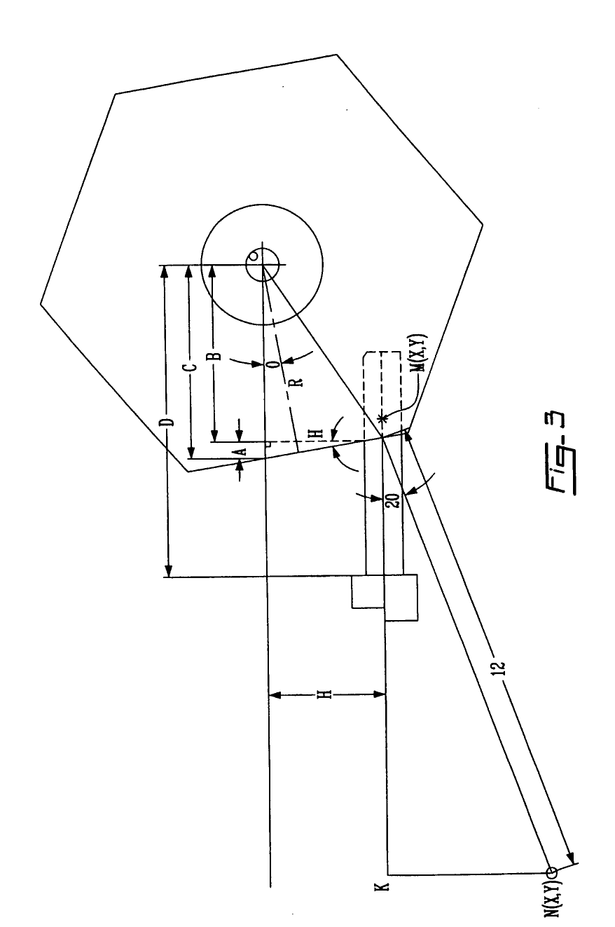

The complex surface of the support is shown in FIG. 2 and the calculation formula for the complex surface of the support is described as follows with reference to FIG. 3:
D—Horizontal distance between laser and wheel center
H—Vertical distance between laser and wheel center
F—Laser focus length (constant)
a—Wheel rotate angle (10°˜54°)
R—Wheel radius
   A=H*tga,C=R/cos a,B=C−A=(R−H*sin a)/cos a
So, Xm=(R−H*sin a)/cos a, Ym=H

In triangle KNM,
Xn=F2*cos 2a,Yn=F2*sin 2a,F1=D−B,F2=F−F1, so,
Xn=(F−D+(R−H*sina)/cos a)*cos 2a,
Yn=(F−D+(R−H*sin a)/cos a)*sin 2a

Using O as origin, so,
X=Xm+Xn=(R−H*sin a)/cos a+(F−D+(R−H*sin a)/cos a)*cos 2a
Y=Ym+Yn=H+(F−D+(R−H*sin a)/cos a)*sin 2a

The cylindrical system is,
N=(a,(x²+y²)^{1/2})

1. An apparatus for high speed scanning of a photosensitive material for image creation, the apparatus comprising:
a support for the material to be scanned for image creation having a lengthwise axis and adapted to support a printing plate;
at least one optoelectronic device for providing an image recording light source;
a light beam optical relay system optically coupling said at least one optoelectronic device with a scanning imaging point on said printing plate, said relay system including:
a rotating mirror for reflecting a beam of light to scan across said printing plate in a transverse direction; and
a gantry for moving said beam in said lengthwise direction across said printing plate,
characterized In that
at least one of said support for the material to be scanned and said rotating mirror is provided with a complex curved shape selected to provide a linear transverse direction scan speed on said printing plate as said mirror rotates at a constant rotational speed, said relay system comprising essentially reflective optics between said gantry and said printing plate, whereby said apparatus operates without the use of an f-θ lens.

2. The apparatus as claimed in claim 1, wherein said rotating mirror is flat with a reflective surface offset from an axis of rotation of said rotating mirror, and said printing plate support is a cylinder including a concavely curved surface.

3. The apparatus as claimed in claim 2, wherein said rotating mirror is multi-faceted, and said scanning imaging point performs a helical scan.

4. The apparatus as claimed in claim 1, wherein said optoelectronic device is a light emitting diode (LED) source.

5. The apparatus as claimed in claim 4, wherein said LED source comprises a plurality of LEDs and a lens arranged to provide a substantially coherent array of n beams for scanning said printing plate.

6. The apparatus as claimed in claim 4, wherein said LED source emits blue light.

7. The apparatus as claimed in claim 5, further comprising means to ensure equality of power in said n beams.

8. The apparatus as claimed in claim 1, wherein said printing plate support comprises vacuum structures for vacuum holding said plate.

9. The apparatus as claimed in claim 1, wherein said rotating mirror comprises a motor, an air bearing rotor, shaft encoder on said rotor, and an electronic control system reading said shaft encoder for controlling said motor to cause said mirror to rotate at a constant speed.

10. An apparatus for high speed scanning of a surface for image capture, the apparatus comprising:
a support for the material to be scanned for image creation or capture having a lengthwise axis and adapted to support a scanning plate;
at least one optoelectronic device for providing an image light detector;
a light beam optical relay system optically coupling said at least one optoelectronic device with a scanning imaging point on said plate, said relay system including:
a rotating mirror for reflecting a beam of light to scan across said plate in a transverse direction; and
a gantry for moving said beam in said lengthwise direction across said plate,
characterized In that
at least one of said support for the material to be scanned and said rotating mirror is provided with a complex curved shape selected to provide a linear transverse direction scan speed on said plate as said mirror rotates at a constant rotational speed, said relay system comprising essentially reflective optics between said gantry and said printing plate, whereby said apparatus operates without the use of an f-θ lens.

11. The apparatus as claimed in claim 10, wherein said rotating mirror is flat with a reflective surface offset from an axis of rotation of said rotating mirror, and said printing plate support is a cylinder including a concavely curved surface.

12. The apparatus as claimed in claim 11, wherein said rotating mirror is multi-faceted, and said scanning imaging point performs a helical scan.

13. The apparatus as claimed in claim 10, wherein said rotating mirror comprises a motor, an air bearing rotor, shaft encoder on said rotor, and an electronic control system reading said shaft encoder for controlling said motor to cause said mirror to rotate at a constant speed.
